(19) United States
(12) Patent Application Publication
(10) Pub. No.: US 2002/0017915 A1
(43) Pub. Date: Feb. 14, 2002

(54) Probe card, probe card restoring method, and probe card manufacturing method

(75) Inventor: Masakazu Kamiya, Tokyo (JP)

Correspondence Address: OLIFF & BERRIDGE, PLC, P.O. BOX 19928, ALEXANDRIA, VA, 22320, US

(73) Assignee: Ando Electric Co., Ltd., Ota-ku (JP)

(21) Appl. No.: 09/897,392

(22) Filed: Jul. 3, 2001

(30) Foreign Application Priority Data
Jul. 17, 2000 (JP) 2000-216242

(51) Int. Cl. G01R 31/02

(52) U.S. Cl. 324/754

(57) ABSTRACT

A probe card used for testing a plurality of integrated circuits formed on a semiconductor wafer, wherein only a part of proves is changeable, a restoring method of the probe card, and a manufacturing method of the probe card. The probe card (1) used for testing a plurality of semiconductor integrated circuits formed on a semiconductor wafer, comprises: a plurality of probes (4) which can electrically conduct to the semiconductor integrated circuits; and a substrate (2) comprising a plurality of welding portions (3a) having no plating layers, to which the probes are welded.

### BACKGROUND OF THE INVENTION

1. Field of the Invention

The present invention relates to a probe card which is used for carrying out a current-carrying test or the like to a plurality of semiconductor integrated circuits formed on a semiconductor wafer, in a state of the semiconductor wafer, all at once, a restoring method of the probe card, and a manufacturing method of the probe card as an object of the restoring method.

2. Description of Related Art

Recently, because a miniaturization of electronic device has been making remarkable progress, a request for a miniaturization of semiconductor integrated circuit provided in the electronic device is increasing. With the request, a method has been developed that the semiconductor integrated circuit is directly mounted on a circuit substrate in the state wherein it is cut off from a semiconductor wafer, that is, in the state of a bear chip. Accordingly, it is required to provide a bear chip that a quality thereof is certified.

In order to certify the quality of the bear chip, it is necessary that a burn-in screening is carried out to all semiconductor integrated circuits in the state of the bear chip. Further, in order to carry out the burn-in screening efficiently, it is required that the burn-in screening is carried out to all semiconductor integrated circuits in the state of the semiconductor wafer before the semiconductor integrated circuits are cut off from the semiconductor wafer, that is, before the semiconductor integrated circuits are bear chips, all at once.

In order to carry out the burn-in screening to the semiconductor integrated circuits in the state of the semiconductor wafer, all at once, it is necessary that a power supply voltage or a signal is applied to each of a plurality of semiconductor integrated circuits formed on the semiconductor wafer, at the same time, to operate the plurality of semiconductor integrated circuits. Therefore, it is necessary to prepare a probe card comprising several thousands of probes thereon. However, it is impossible that a needle type of probe card according to an earlier development comprises several thousands of probes, in view of the number and the cost of probes.

Accordingly, a probe card 200 as shown in FIG. 3 is disclosed in Japanese Patent Publication (Laid-open) No. Tokuhyo-hei 10-506197 and Japanese Patent Application (Laid-open) No. Tokukai 2000-67953, wherein a very small spring is formed on a substrate in order to connect a semiconductor integrated circuit to the substrate according to a wire-bonding method.

As shown in FIG. 3, the probe card 200 has a structure that a probe 201 is bonded to a terminal 203 on a substrate 202.

The probe 201 comprises a wire core 201a, an internal layer 201b for covering the wire core 201a, and an external layer 201c for covering the internal layer 201d.

The wire core 201a is made of soft metal such as gold or the like, used in the wire-bonding method. Further, the wire core 201a is cut like a spring-shape suitable for the wire-bonding method, and formed on the terminal 203 provided on the substrate 202.

The internal layer 201b and the external layer 201c are plated. The internal layer 201b is made of hard material so as to have a spring. The external layer 201c is made of superior anti-oxidizing and conductive material.

After the probe 201 suitable for the wire-bonding method is formed out of the soft metal, the probe 201 is plated. Therefore, it is impossible that only a failure part is restored, when a manufacture failure occurs at a part of several thousands of probes 201 formed, or when a partial failure occurs after continuously using the probes 201. Accordingly, it has been necessary that all probes are provided on the substrate, after all proves were removed from the substrate.

### SUMMARY OF THE INVENTION

The present invention was developed in order to solve the problems as mentioned above.

An object of the present invention is to provide a probe card used for testing a plurality of integrated circuits formed on a semiconductor wafer, wherein only a part of proves is changeable, a restoring method of the probe card, and a manufacturing method of the probe card.

In accordance with a first aspect of the present invention, according to a probe card (for example, a probe card 1 shown in FIG. 1) used for testing a plurality of semiconductor integrated circuits formed on a semiconductor wafer, the probe card comprises: a plurality of probes (for example, a probe 4 shown in FIG. 1) which can electrically conduct to the semiconductor integrated circuits; and a substrate (for example, a wiring substrate 2 shown in FIG. 1) comprising a plurality of welding portions (for example, a solder 3a shown in FIG. 2) having no plating layers, to which the probes are welded.

Herein, the probe card is used for carrying out a carrying-current test or the like to the semiconductor integrated circuits formed on the semiconductor wafer, all at once.

The welding portion of the substrate means one melting at a lower melting point than one of the plating layer. Further, when the welding portion is solidified after having melted once, the welding portion welds the probe thereto.

The plating layer means a thin layer covering a surface of the welding portion to prevent the welding portion from oxidizing and so on.

In accordance with a second aspect of the present invention, according to a restoring method of a probe card used for testing a plurality of semiconductor integrated circuits formed on a semiconductor wafer, the probe card comprising: a plurality of probes which can electrically conduct to the semiconductor integrated circuits; and a substrate comprising a plurality of welding portions having no plating layers, to which the probes are welded; the restoring method comprises the steps of: melting the welding portion to which the probe determined to be faulty is welded, by irradiating the welding portion with a light emitted from a heat source (for example, a laser light emitting unit 10 shown in FIG. 2); detaching the probe from the welding portion melted; and welding another probe to the welding portion melted.

According to the probe card of the first aspect of the present invention, it is possible to provide the probe card which can be restored by the restoring method of the second aspect of the present invention.

According to the restoring method of the second aspect of the present invention, because the welding portion to which the probe is welded is melted with the light emitted from the heat source, it is possible that only the welding portion to which the desired probe is welded is melted without melting the welding portion to which the probe next to the desired probe is welded.

When the welding portion is melted with the light, because the welding portion to which of the substrate the probe is welded does not have a plating layer, it is possible that the welding portion is certainly melted if a melting point of a plating metal of the plating layer is high.

Consequently, it is possible only a part of probes is detached from the substrate, and changed to another new probe that is not faulty.

Preferably, according to the restoring method of a probe card, of the second aspect of the present invention, the light is a laser light (for example, a laser light emitted from a laser light emitting unit 10 shown in FIG. 2).

According to the restoring method as described above, because the laser light having a strong directivity is used as the light emitted from the heat source, it is possible that only the welding portion to which the desired probe is welded is more certainly melted without melting the welding portion to which the probe next to the desired probe is welded.

In accordance with a third aspect of the present invention, according to a manufacturing method of a probe card used for testing a plurality of semiconductor integrated circuits formed on a semiconductor wafer, the probe card comprising: a plurality of probes which can electrically conduct to the semiconductor integrated circuits; and a substrate comprising a plurality of welding portions having no plating layers, to which the probes are welded; the manufacturing method comprises the steps of: plating the probes; and welding the probes plated to the welding portions irradiated with lights emitted from a heat source (for example, a laser light emitting unit 10 shown in FIG. 2).

Herein, the plating means a metal plating including an electroplating, a non-electroplating and so on.

According to the manufacturing method of the third aspect of the present invention, because only the desired welding portion is melted, it is possible that the probes are welded to the welding portions at small intervals. Further, because the probes are welded to the welding portions after being plated, it is possible to easily manufacture the probe card of the first aspect of the present invention.

Preferably, the manufacturing method of a probe card, of the third aspect of the present invention, further comprises the steps: applying solders (for example, a solder 3a show in FIG. 2) to the welding portions; and welding the probes to the welding portions by melting the solders.

Herein, the solder means an alloy having a melting point lower than 450 degrees centigrade.

According to the manufacturing method as described above, because the solder having a low melting point is previously applied to the welding portion, it is possible to weld the probe to the welding portion easily. Further, it is possible to weld the probe to the welding portion with a smaller heat capacity.

In accordance with a fourth aspect of the present invention, according to a probe card used for testing to a plurality of semiconductor integrated circuits formed on a semiconductor wafer, the probe card comprises: a plurality of probes which can electrically conduct to the semiconductor integrated circuits; a substrate including a plurality of leads insulated from one another; and a plurality of solder layers for connecting the probes to the leads of the substrate mechanically and electrically.

Preferably, according to the probe card of the fourth aspect of the present invention, the probe is formed like an approximate S-shape, and an upper surface and a bottom surface of the probe are flat.

According to the probe card as described above, because the probe is formed like an approximate S-shape, when an external force is applied to the probe, the external force can be absorbed in an elastic transformation of the probe. As a result, it is hard that a contact surface wherein the probe is contacted with the semiconductor integrated circuit deviates.

### BRIEF DESCRIPTION OF THE DRAWINGS

The present invention will become more fully understood from the detailed description given hereinbelow and the accompanying drawings which are given by way of illustration only, and thus are not intended as a definition of the limits of the present invention, and wherein;

FIG. 1 is a schematic perspective view of a probe card according to an embodiment of a probe card of the present invention;

FIG. 2 is a schematic perspective view for explaining a main step of manufacturing steps of the probe card shown in FIG. 1; and

FIG. 3 is a sectional view of an exemplary probe card according to an earlier development.

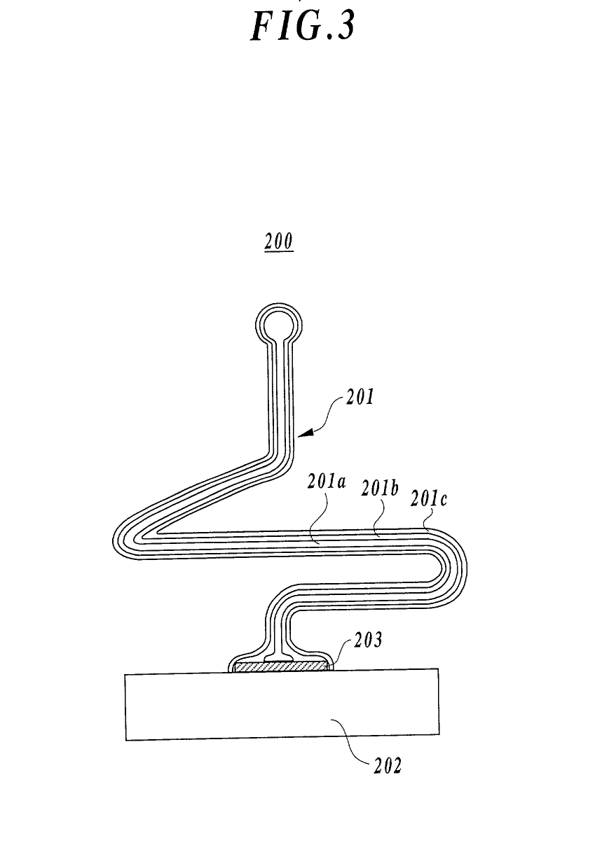

### PREFERRED EMBODIMENT OF THE INVENTION

Hereinafter, an embodiment of the present invention will be explained with reference to figures, in detail.

First, a structure of a probe card 1 will be explained, as follows.

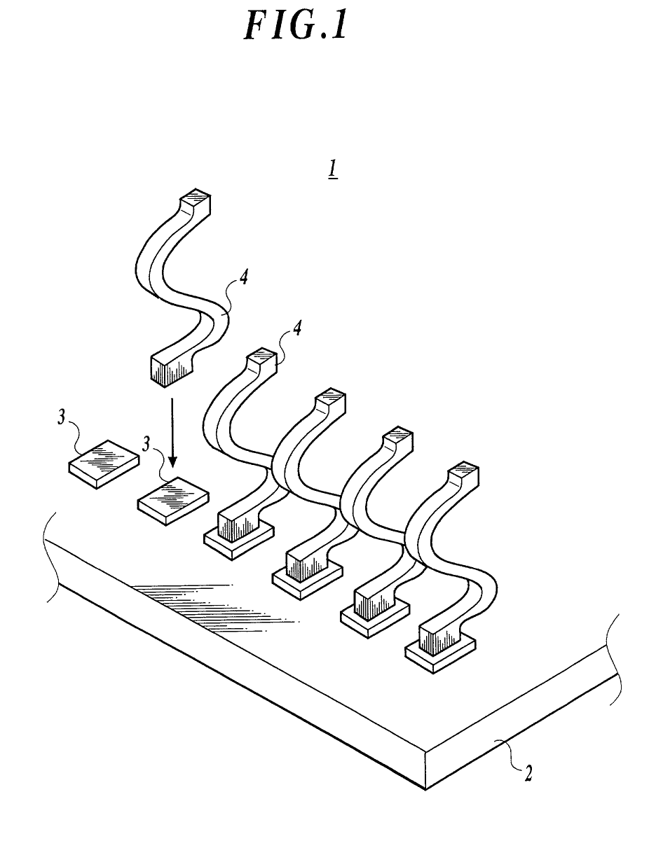

As shown in FIG. 1, the probe card 1 primarily comprises a wiring substrate 2, a plurality of pads 3 provided on the wiring substrate 2, and a plurality of probes 4 soldered on the pads 3.

The wiring substrate 2 comprises a plurality of wires that are leads provided thereon and insulated from one another, in order to apply a power supply voltage, a signal or the like for carrying out a carrying-current test or the like to a plurality of semiconductor integrated circuits formed on a semiconductor wafer, to the semiconductor integrated circuits, all at once.

The pad 3 is used for electrically connecting the probe 4 to the lead of the wiring substrate 2. The pad 3 is formed on the wiring substrate 2 by providing a metallic layer on a surface of the wiring substrate 2. Because, for example, several thousands of pads 3 are provided on the wiring substrate 2, it is possible that a plurality of semiconductor integrated circuits formed on the semiconductor wafer, are tested all at once.

The probe 4 is pressure-contacted with each testing electrode of the semiconductor wafer, such that the wiring substrate 2 is electrically connected to the semiconductor integrated circuit through the probe 4.

More specifically, the probe 4 is made of hard metal that includes a metal such as a nickel, a chrome or an iron, an alloy a principal ingredient of which is the metal, and so on. Further, the probe 4 is formed like an approximate S-shape, and upper and bottom surfaces of the probe 4 are flat. Therefore, the bottom surface of the probe 4 is bonded to the pad 3, and the upper surface of the probe 4 is pressure-contacted with the semiconductor integrated circuit.

Herein, because the probe 4 is made of hard metal, it is unnecessary that the probe 4 is plated in order to have a more strength.

Further, because the probe 4 is formed like the above-described shape, when an external force is applied to the probe 4, the probe 4 is transformed elastically. Accordingly, the vertical pressure on a surface of the probe 4 when the probe 4 is pressure-contacted with the semiconductor integrated circuit on the semiconductor wafer is absorbed in the elastic transformation of the probe 4.

That is, because the probe 4 absorbs the unnecessary pressure, the probe 4 is contacted with each testing electrode of the above-described semiconductor wafer under proper pressure. Further, because the probe 4 is formed like the above-described shape, the force acting in the rectangular direction to the proper pressure is absorbed sufficiently. Accordingly, it is hard that the contact surface on which the probe 4 is contacted with the semiconductor integrated circuit deviates.

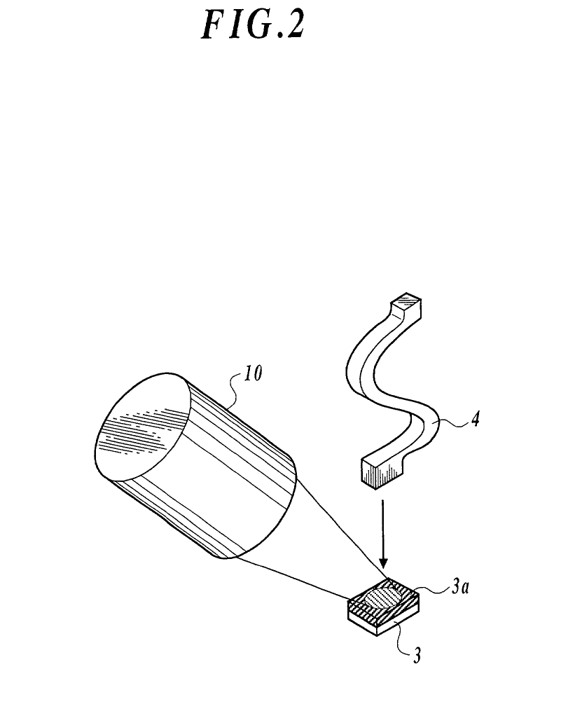

Next, the manufacturing method of the probe card 1 will be explained with reference to FIG. 2, as follows.

In order to prevent the probe 4 from oxidizing and so on, a general metal plating such as an electroplating, a non-electroplating or the like is previously performed to the probe 4.

Further, a proper quantity of solder 3a is previously applied on the pad 3 of the wiring substrate 2, as a welding portion for welding the probe 4 to the pad 3.

As shown in FIG. 2, lights emitted from a laser light emitting unit 10 of the semiconductor or the like, are gathered through a lens not shown in figures, to irradiate the solder of the pad 3 therewith.

When the solder 3a melts on the pad 3, the probe 4 held by a holding unit not shown in figures is moved down as a position, an inclination and a height of the probe 4 are controlled, such that the bottom surface of the probe 4 is contacted with the pad 3. When the position, the inclination and the height of the probe 4 are determined, the laser light emitting unit 10 stops emitting lights. Thereby, because the solder 3a is solidified, the probe 4 is welded to the pad 3.

In the above-described steps, when a predetermined number of probes 4 are melt-bonded to the pads 3, the manufacturing process of the probe card 1 finishes.

Next, the restoring method of the probe card 1 will be explained that the probe 4 determined to be faulty is changed to another probe which is not faulty, as follows.

First, when the probe 4 to be changed to another probe is held by the above-described holding unit, the laser light emitting unit 10 irradiates the solder 3a that is the welding portion welding the probe 4 to the pad 3 with laser lights emitted therefrom.

Thereby, because the metal plating is previously performed to the probe 4, but the plating is not performed to the welding portion welding the probe 4 to the pad 3, the solder 3a of the pad 3 melts with laser lights. Thereafter, when the solder 3a has melted, the probe 4 is raised by the holding unit and detached from the pad 3.

In the above-described steps, another probe 4 is welded to the pad 3 over again.

Because the solder 3a welding the probe 4 to the pad 3 is melted with the laser lights gathered, if the pads 3 are arranged at small intervals on the wiring substrate 2, it is possible that only the desired solder 3a melts without affecting another solder 3a welding the next probe 4 to the next pad 3.

Further, because the solder 3a is heated properly by controlling the laser light irradiation time, it is possible that the solder 3a is melted if the size of each pad 3 is not equal to one of another pad 3.

According to the embodiment of the present invention, it is possible that only the faulty probe 4 is changed to another one, without affecting the quality of the probe card 1.

Although the present invention has been explained according to the above-described embodiment, it should also be understood that the present invention is not limited to the embodiment and various chanted and modifications may be made to the invention without departing from the gist thereof.

For example, the light as the heat source is not limited to the laser light, and may be any one that can heat the solder 3a sufficiently.

Further, the shape or the like of the probe 4 is set voluntarily. It is needless to say that specific each component can be modified as the occasion may demand.

According to the present invention, some effects will be indicated, as follows.

According to the above-described restoring method, it is possible that only the faulty probe is changed to another probe which is not faulty.

Further, according to the above-described manufacturing method, it is possible to manufacture the probe card easily.

Further, because the solder having a low melting point is previously applied to the welding portion, it is possible to bond the probe to the substrate easily. Further, it is possible to weld the probe to the welding portion with a smaller heat capacity.

The entire disclosure of Japanese Patent Application No. Tokugan 2000-216242 filed on Jul. 17, 2000 including specification, claims, drawings and summary are incorporated herein by reference in its entirety.

What is claimed is:

1. A probe card used for testing a plurality of semiconductor integrated circuits formed on a semiconductor wafer, the probe card comprising:
a plurality of probes which can electrically conduct to the semiconductor integrated circuits; and
a substrate comprising a plurality of welding portions having no plating layers, to which the probes are welded.

2. A restoring method of a probe card used for testing a plurality of semiconductor integrated circuits formed on a semiconductor wafer, the probe card comprising:
a plurality of probes which can electrically conduct to the semiconductor integrated circuits; and
a substrate comprising a plurality of welding portions having no plating layers, to which the probes are welded; wherein the restoring method comprises the steps of:
melting the welding portion to which the probe determined to be faulty is welded, by irradiating the welding portion with a light emitted from a heat source;
detaching the probe from the welding portion melted; and
welding another probe to the welding portion melted.

3. A restoring method of a probe card, as claimed in claim 2, wherein the light is a laser light.

4. A manufacturing method of a probe card used for testing a plurality of semiconductor integrated circuits formed on a semiconductor wafer, the probe card comprising:
a plurality of probes which can electrically conduct to the semiconductor integrated circuits; and
a substrate comprising a plurality of welding portions having no plating layers, to which the probes are welded; wherein the manufacturing method comprises the steps of:
plating the probes; and
welding the probes plated to the welding portions irradiated with lights emitted from a heat source.

5. A manufacturing method of a probe card, as claimed in claim 4, further comprising the steps:
applying solders to the welding portions; and
welding the probes to the welding portions by melting the solders.

6. A probe card used for testing to a plurality of semiconductor integrated circuits formed on a semiconductor wafer, the probe card comprising:
a plurality of probes which can electrically conduct to the semiconductor integrated circuits;
a substrate including a plurality of leads insulated from one another; and
a plurality of solder layers for connecting the probes to the leads of the substrate mechanically and electrically.

7. A probe card as claimed in claim 6,
wherein the probe is formed like an approximate S-shape, and an upper surface and a bottom surface of the probe are flat.
